(19) United States
(12) Patent Application Publication
(10) Pub. No.: US 2005/0083093 A1
(43) Pub. Date: Apr. 21, 2005

(54) Flip-flop

(76) Inventor: Young-Chul Rhee, Yongin-si (KR)

Correspondence Address: HARNESS, DICKEY & PIERCE, P.L.C., P.O. BOX 8910, RESTON, VA, 20195, US

(21) Appl. No.: 10/873,178

(22) Filed: Jun. 23, 2004

(30) Foreign Application Priority Data
Oct. 15, 2003 (KR) 2003-71805

(51) Int. Cl. H03K 3/289

(52) U.S. Cl. 327/218

(57) ABSTRACT

A flip-flop can include: a first switching circuit operable to transfer, for a significant amount of time after a clock signal changes to an active level, a received signal to a first node; an inverter operable to invert a signal on the first node and to output the inverted signal to a second node; a second switching circuit operable to transfer the received data signal on the first node and the inverted signal on the second node to third and fourth nodes, respectively, as output signals in response to the clock signal; and a latch operable to latch signals transferred to the third and fourth nodes.

### CROSS-REFERENCE TO RELATED APPLICATIONS

This U.S. non-provisional patent application claims priority under 35 U.S.C. §119 of Korean Patent Application 2003-71805 filed on Oct. 15, 2003, the entire contents of which are hereby incorporated by reference.

### BACKGROUND OF THE PRESENT INVENTION

A data type of flip-flop (hereinafter, referred to as D flip-flop) is configured to “read” a data input at a particular point in each clock cycle. The output of the D flip-flop provides the value that was read, independent of subsequent changes, or noise, on the data input, until the next data value is read. The data input must be stable while it is being read into the D flip-flop, else the read value may be indeterminable. Ideally, the reading of the data input occurs instantaneously, so that the sensitivity of the D flip-flop to changes on the data input is minimized. Also ideally, the instantaneous read occurs at exactly the same point within each clock cycle.

The performance of a D flip-flop is assessed in terms of its cycle delay, or “sequencing overhead”, and its power consumption. The sequencing overhead is defined herein as the minimum time required to read the data into the device and to produce a stable output corresponding to this data. This includes any set-up requirements imposed on the data input to assure a reliable read of the data value, plus the time required to propagate the data from the input to the output of the device. This sequencing overhead corresponds, inversely, to the maximum speed that a serial string of D flip-flops can be reliably operated. If the D flip-flop includes additional internal logic, such as scan logic that is used for testing the device, the sequencing overhead includes an impact, if any, that the additional internal logic imposes on the propagation of the data input to the output of the D flip-flop during normal (i.e. performance) operation. The power consumption of a D flip-flop typically depends upon the energy required to change the state of the elements within the D flip-flop, and hence, is typically dependent upon the pattern of data values read by the D flip-flop. Generally, the power consumption of a D flip-flop is estimated based upon an assumed random data input pattern to the D flip-flop.

FIGS. 1 to 3 are circuit diagrams of D flip-flops according to the Background Art. Referring to Background Art FIG. 1, the flip-flop 100 includes tri-state buffers 112 and 131, inverters 110, 111, 151 and 152, latches 120 and 140. The inverters 110 and 111 are connected in series and receive clock signal CLK. The tri-state buffer 112 transfers data signal D to the latch 120 in response to outputs of the inverters 110 and 111. The latch 120 is provided with inverters 121 and 122 that are connected back-to-back. In response to the clock signal CLK, the latch 120 latches the inverted data signal from the tri-state buffer 112. The tri-state buffer 131 inverts an output of the latch 120 in response to the outputs of the inverters 110 and 111. The data signal outputted from the tri-state buffer 131 is outputted as an output signal Q through the inverter 151. The latch 140 is provided with inverters 141 and 142 that are connected back-to-back. The latch 140 latches the output of the tri-state buffer 131 in response to the clock signal CLK.

The Background Art flip-flop 100 outputs the data signal D as the output signal Q when the clock signal CLK changes to a high level. However, before the data signal D can be outputted as the output signal Q, the data signal D must pass through four elements 112, 121, 131 and 151, resulting in an increase of time delay.

FIG. 2 is a circuit diagram of another flip-flop having an improved operating speed according to the Background Art.

Referring to Background Art FIG. 2, the flip-flop 200 includes a delay circuit 210, transmission gates 220 and 230, a latch 240, and inverters 251 to 254. The delay circuit 210 includes inverters 211, 212 and 215 that are connected in series. The delay circuit 210 inverts and delays a clock signal CLK. The inverter 252 inverts an output of the delay circuit 210 and the inverter 253 inverts the clock signal CLK. The transmission gate 220 includes NMOS transistor 221 and PMOS transistor 222 and transfers data signal D as an output signal in response to outputs of the delay circuit 210 and the inverter 252. The transmission gate 230 includes NMOS transistor 231 and PMOS transistor 232 and transfers an output of the transmission gate 220 in response to the clock signal CLK and an output of the inverter 253. The latch 240 includes inverters 241 and 242 that are connected back-to-back and latches an output of the transmission gate 230. Specifically, in order to prevent loss that may occur when the transmission gate 220 transfers the data signal D, output terminals of the transistors 221 and 222 of the transmission gate 220 are separated and connected to the transistors 231 and 232 of the transmission gate 230, respectively.

The Background Art flip-flop 200 constructed as above propagates data signal D to the transmission gate 230 while the clock CLK is at a low level. Then, when the clock signal CLK changes to a high level, the propagated data signal are outputted as the output signal Q through the transmission gate 230 and the inverter 254.

In order to increase an operating speed, the transmission gate 230 of the Background Art flip-flop 200 is configured to operate in response to the clock signal CLK that is not delayed. However, since the data signal D passes through the four elements 251, 220, 230 and 254, the delay time is still long. In addition, since the transmission gate 230 is driven by the output of the inverter 253, an additional delay occurs due to skew.

FIG. 3 is a circuit diagram of a still other D flip-flop according to the Background Art.

Referring to Background Art FIG. 3, the flip-flop 300 includes a delay circuit 310, a latch 320, transmission gates 331 to 336, and inverters 341 to 343. The delay circuit 310 includes inverters 311 to 313 that are connected in series. The delay circuit 310 inverts and delays a clock signal CLK. Transistors 331 to 333 are connected in series between a differential node 301 and ground voltage. Transistors 334 to 336 are connected in series between a differential node 302 and the ground voltage. Each of the transistors 331 and 334 has a gate connected to the clock signal CLK. Each of the transistors 332 and 335 has a gate connected to an output of the delay circuit 310. The transistor 333 has a gate connected to data signal D and the transistor 336 has a gate connected to an inverted data signal, i.e., an output of the inverter 341. The signal on the differential node 301 is inverted by the inverter 343 and is outputted as an output signal Q. The latch 320 includes inverters 321 and 322 that are connected back-to-back between the differential nodes 301 and 302. The latch 320 maintains values of the differential nodes 301 and 302 until a new data signal is inputted.

In the Background Art flip-flop 300 constructed as above, a two-stage delay occurs in order to output the data signal D as the output signal Q when the clock signal CLK changes from a low level to a high level. The delay time is the sum of a time taken to propagate data signal D to the node 301 through the transistor 331 and a time taken to propagate data signal D to the node 302 through the inverter 322. However, three NMOS transistors 331 to 333 are connected in series between the node 301 and the ground and three NMOS transistors 334 to 336 are connected in series between the node 302 and the ground, which degrades the capability of driving the nodes 301 and 302. In other words, it takes a long time to discharge the nodes 301 and 302.

### SUMMARY OF THE INVENTION

At least one embodiment of the present invention provides a flip-flop that can include: a first switching circuit operable to transfer, for a significant amount of time after a clock signal changes to an active level, a received signal to a first node; an inverter operable to invert a signal on the first node and to output the inverted signal to a second node; a second switching circuit operable to transfer the received data signal on the first node and the inverted signal on the second node to third and fourth nodes, respectively, as output signals in response to the clock signal; and a latch operable to latch signals transferred to the third and fourth nodes.

Additional advantages and features of the present invention will be set forth in part in the description which follows and in part will become apparent to those having ordinary skill in the art upon examination of the following or may be learned from practice of the present invention. At least some of the advantages of the present invention may be realized and attained by the structure particularly pointed out in the written description as well as the appended drawings.

It is to be understood that both the foregoing general description and the following detailed description of the present invention are exemplary and explanatory and are intended to provide further explanation of the present invention.

### BRIEF DESCRIPTION OF THE DRAWINGS

The accompanying drawings, which are included to provide a further understanding of the present invention and are incorporated in and constitute a part of this application, illustrate embodiment(s) of the present invention and together with the description serve to explain the principle of the present invention. In the drawings:

FIG. 1 is a circuit diagram of a D flip-flop according to the background art;

FIG. 2 is a circuit diagram of another D flip-flop having an improved operating speed according to the Background Art;

FIG. 3 is a circuit diagram of still other D flip-flop having an improved operating speed according to the Background Art;

FIG. 4 is a circuit diagram of a D flip-flop according to at least one embodiment of the present invention; and

FIGS. 5A to 5C illustrate comparison results of the Background Art of FIGS. 1 to 3 versus the present invention of FIG. 4 in terms of operating speed, power consumption, and a product of the operating speed and the power consumption.

### DETAILED DESCRIPTION OF THE INVENTION

Reference will now be made in detail to example embodiments of the present invention, examples of which are illustrated in the accompanying drawings. However, the present invention is not limited to the embodiments illustrated herein after, and the embodiments herein are rather introduced to provide easy and complete understanding of the scope and spirit of the present invention.

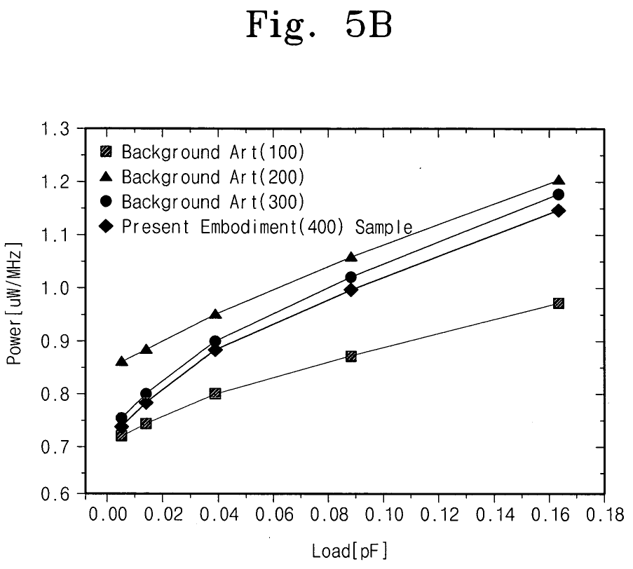

FIG. 4 is a circuit diagram of a D flip-flop according to a preferred embodiment of the present invention. Referring to FIG. 4, the D flip-flop 400 includes: a first switching circuit 408; an inverter 443 connected between nodes 401 and 402; a second switching circuit 450 connected between the node 401 and an output node 403, and between the node 402 and an output node 404, respectively, and configured to transfer a data signal on the node 401 to the output node 403 and a data signal on the node 402 to the output node 404; a latch 430; and inverters 444 and 445. The first switching circuit 408 includes a delay circuit 410, a transmission gate 420, and inverters 441 and 442. The second switching circuit includes a switch element 451 arranged between the nodes 401 and 403 and a switch element 452 arranged between the nodes 402 and 404.

The inverter 441 receives the data signal D and outputs an inverted data signal to a node 405. The transmission gate 420 is connected to the node 405. Where nodes 401-404 are described as first through fourth nodes, then the node 405 can be described as a zeroith node.

The delay circuit 410 includes inverters 411 to 413 that are connected in series. The delay circuit 410 inverts and delays a clock signal CLK. Further discussion of the delay circuit 410 is to be found below. The inverter 442 is connected to an output of the delay circuit 410. The transmission gate 420 includes an NMOS transistor 421 and a PMOS transistor 422. Current paths of the transistors 421 and 422 are formed between an output of the inverter 441 and the node 401. The transistor 421 has a gate connected to the output of the delay circuit 410 and the transistor 422 has a gate connected to an output of the inverter 442. Thus, the transmission gate 420 transfers the data signal D to the node 401 while the clock signal CLK is at a low level.

The transmission gate 420 retains the data signal, which is received via the inverter 441, on the node 401 for a delay time of the delay circuit 410 after the clock signal CLK changes from an inactive level to an active level, e.g., from a low level to a high level.

The inverter 443 is connected between the nodes 401 and 402. The switch elements 451 and 452 can be, e.g., NMOS transistors. The NMOS transistor 451 is connected between the node 401 and the output node 403 and is controlled by the clock signal CLK. The NMOS transistor 452 is connected between the node 402 and the output node 404 and is controlled by the clock signal CLK. If the clock signal CLK is activated to a high level, the NMOS transistors 451 and 452 transfer the signals of the nodes 401 and 402 to the output nodes 403 and 404, respectively.

The latch 430 includes inverters 431 and 432 that are cross coupled between the output nodes 403 and 404. The latch 430 latches the signals of the output nodes 403 and 404. The inverters 444 and 445 invert the signals of the output nodes 403 and 404 and outputs signals Q and Qn, respectively.

An operation of the flip-flop 400 will now be described below. First, while the clock signal CLK is at a low level, data signal D is transferred to the node 401 through the inverter 441 and the transmission gate 420. At this time, the transistors 451 and 452 are in turned-off states, so that the signal of the node 401 is not transferred to the output nodes 403 and 404.

If the clock signal CLK changes from a low level to a high level, then the transistors 451 and 452 become turned on, so that the data signals on the nodes 401 and 402 are transferred to the output nodes 403 and 404, respectively. Thus, the data output signal Q is outputted through the output node 403 and the inverted data output signal Qn is outputted through the output node 404.

Meanwhile, despite the clock signal CLK having changed from a low level to a high level, the inverted data signal D continues temporarily to be transferred through the transmission gate 420 to the node 401 for the delay time of the delay circuit 410. Upon elapse of the delay time, the change in the clock signal (again, from a low level to a high level) reaches the transmission gate 420, causing the transmission gate 420 to become turned off, which results in the data signal D no longer being transferred to the node 401. Thus, the data output signals Q and Qn outputted through the output nodes 403 and 404 are maintained by the latch 430.

If the delay circuit 410 was not present, then there might still be a difference in time between when the transistors 451 and 452 turn on and when the transmission gate 420 turns off, e.g., due to differences in signal path lengths, respective transistor physics, etc., but such a difference would be negligible. In contrast, the delay circuit 410 induces a delay that is at the least of significant magnitude relative to the above-noted negligible difference (or, in other words, negligible delay amount).

The flip-flop 400 can store the data signal D to the node 401 using as few as one switch, that is, the transmission gate 420. When the clock signal CLK is activated to a high level, the data signal stored on the node 401 is transferred to the node 403 as the data output signal Q through as few as one switch, that is, the NMOS transistor 451. And when the clock signal CLK is activated to a high level, it also occurs that the inverted data signal stored on the node 402 outputted is transferred to the node 404 as the inverted data output signal Qn through as few as one switch, that is, the NMOS transistor 452. Thus, when the clock signal CLK changes from a low level to a high level, the output delay time of the data output signal Q corresponds to the delay attributed to propagation of the data signal through the NMOS transistor 451 and the inverter 444. Similarly, when the clock signal CLK changes from a low level to a high level, the output delay time of the data output signal Qn corresponds to the delay attributed to propagation of the data through the inverter 443, the NMOS transistor 452 and the inverter 445.

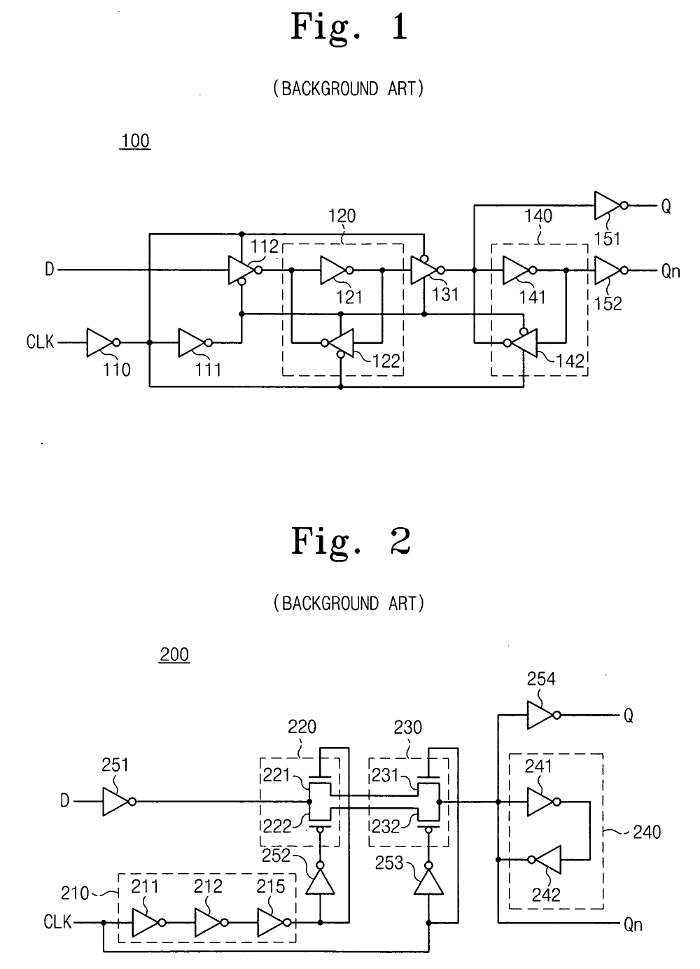

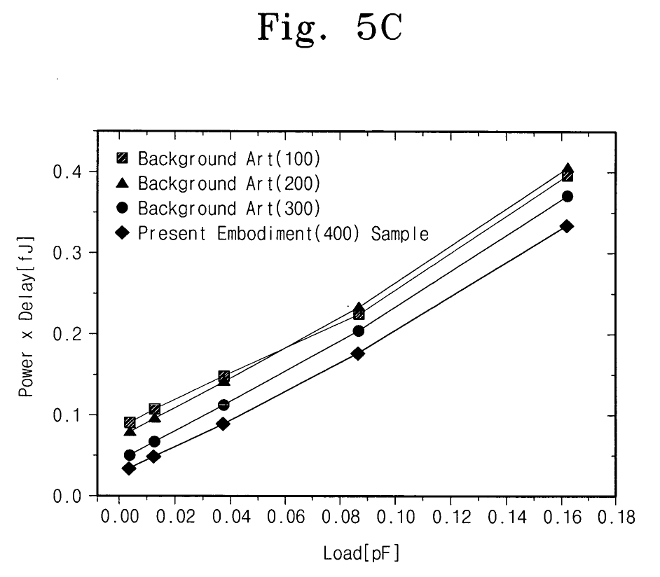

FIGS. 5A to 5C illustrate comparison results of the Background Art of FIGS. 1 to 3 versus a sample implementation for the D flip-flop 400 of FIG. 4 in terms of operating speed (FIG. 5A), power consumption (FIG. 5B), and a product of the operating speed and the power consumption (FIG. 5C). In order to provide equal evaluation conditions, the transistors used in the respective flip-flops have the same size. Also, load capacitances of the output nodes are changed in order to obtain the evaluation result.

Referring to FIG. 5A, an operating speed (delay speed) of the flip-flop 400 is higher than that of the flip-flops 100, 200 and 300 according to the Background Art. Specifically, the flip-flop 400 has an improved delay speed by 44% compared with the flip-flops 100 of FIG. 1.

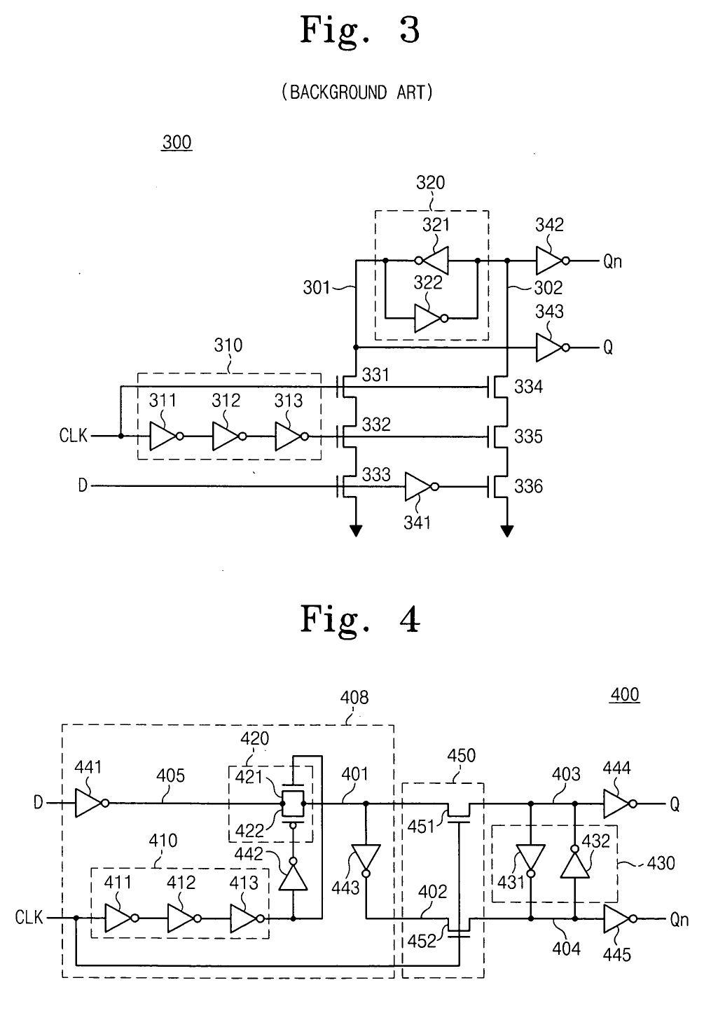

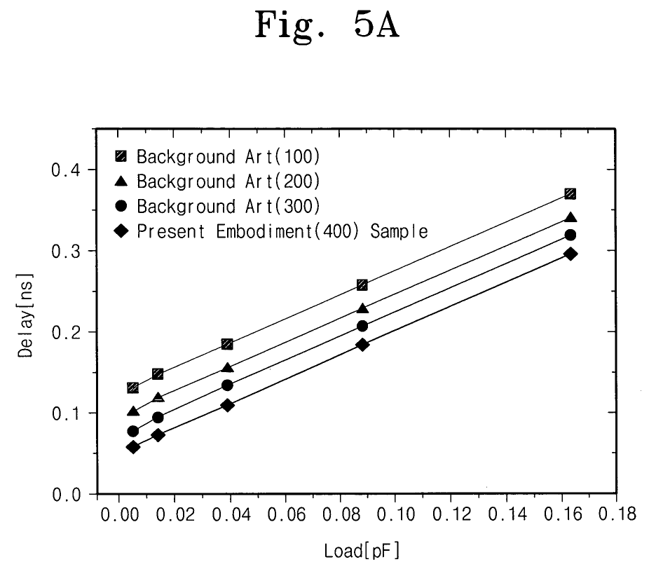

Referring to FIG. 5B, the power consumption of the flip-flop 400 is lower than that of the flip-flops 200 and 300 of FIGS. 2 and 3 but higher than the flip-flop 100 of FIG. 1. However, the flip-flop 400 has a smaller product of the operating speed and the power consumption by 37% compared with flip-flop 100 of FIG. 1. This is because the flip-flop 400 has a two-stage delay as contrasted with the four-stage delay of Background Art flip-flop 100, relative to a transition of the clock signal. That is, flip-flop 400 exhibits a delay attributed to the CLK-controlled the transistor 451 and the inverter 444, while the flip-flop 100 of FIG. 1 outputs the data signal with a four-stage delay from the inverted clock signal.

According to at least one embodiment of the present invention, it is possible to implement a flip-flop that has an improved operating speed and a low power consumption.

It will be apparent to those skilled in the art that various modifications and variations can be made in the present invention. Thus, it is intended that the present invention covers the modifications and variations of this present invention.

1. A flip-flop comprising:
a first switching circuit operable to transfer, for a significant amount of time after a clock signal changes to an active level, a received signal to a first node;
an inverter operable to invert a signal on the first node and to output the inverted signal to a second node;
a second switching circuit operable to transfer the received data signal on the first node and the inverted signal on the second node to third and fourth nodes, respectively, as output signals in response to the clock signal; and
a latch operable to latch signals transferred to the third and fourth nodes.

2. The flip-flop of claim 1, wherein the first switching circuit includes:
a delay circuit operable to delay the clock signal;
an inverter operable to invert the delayed clock signal from the delay circuit; and
a transmission gate operable to transfer the received data signal to the first node in response to outputs of the delay circuit and the inverter.

3. The flip-flop of claim 1, wherein the second switching circuit includes:
a first switch element, connected between the first node and the third node, operable to transfer the data signal on the first node to the third node in response to the clock signal; and
a second switch element, connected between the second node and the fourth node, operable to transfer the inverted signal of the second node to the fourth node in response to the clock signal.

4. The flip-flop of claim 3, wherein the first switch element is an NMOS transistor having a drain connected to the first node, a source connected to the third node, and a gate receiving the clock signal.

5. The flip-flop of claim 3, wherein the second switch element is an NMOS transistor having a drain connected to the second node, a source connected to the fourth node, and a gate receiving the clock signal.

6. The flip-flop of claim 1, wherein the latch includes two inverters connected back-to-back between the third and fourth nodes.

7. A flip-flop comprising:
a switching circuit for transferring, for a significant amount of time after a clock signal changes to an activated level, a received signal to a first node;
an inverter for inverting a signal on the first node and outputting the inverted signal to a second node;
a first switch element for transferring the received signal on the first node to a third node as an output signal in response to the clock signal;
a second switch element for transferring the inverted signal on the second node to a fourth node as another output signal in response to the clock signal; and
a latch for latching signals transferred to the third and fourth nodes.

8. The flip-flop of claim 7, wherein the switching circuit includes:
a delay circuit for delaying the clock signal;
an inverter for inverting an output of the delay circuit; and
a transmission gate for transferring the data signal to the first node in response to outputs of the delay circuit and the inverter.

9. The flip-flop of claim 7, wherein the latch includes two inverters connected back-to-back between the third and fourth nodes.

10. A flip-flop comprising:
a first switching circuit operable to transfer, for a significant amount of time after a clock signal changes to an active level, a received signal to a first node;
an inverter operable to invert a signal on the first node and to output the inverted signal to a second node;
a first transistor having a current path formed between the first node and a third node, the first transistor having a gate receiving the clock signal;
a second transistor having a current path formed between the second node and a fourth node, the second transistor having a gate receiving the clock signal; and
a latch for latching signals transferred to the first and second output nodes.

11. The flip-flop of claim 10, wherein the first and second transistors are NMOS transistors.

12. The flip-flop of claim 10, wherein the switching circuit includes:
a delay circuit operable to delay the clock signal;
an inverter operable to invert the delayed clock signal from the delay circuit; and
a transmission gate operable to transfer the received data signal to the first node in response to outputs of the delay circuit and the inverter.

13. The flip-flop of claim 10, wherein the latch includes two inverters connected back-to-back between the third and fourth nodes.

14. A method of operating a flip-flop, the method comprising:
putting a received data signal on a zeroith node;
permitting electrical conduction, while a clock signal exhibits an inactive level, between the zeroith node and a first node to attain on the first node a first signal substantially the same as the data signal;
permitting electrical conduction, when the clock signal exhibits an active level, between the first node and a third node to attain on the third node a third signal substantially the same as the first signal;
maintaining electrical conduction between the zeroith node and the first node for a significant amount of time after the clock signal changes to an active level;
suppressing electrical conduction, after elapse of the significant amount of time, between the zeroith node and the first node; and
latching the third signal on the third node.

15. The method of claim 14, further comprising:
inverting the first signal;
putting the inverted first signal on a second node as a second signal;
permitting electrical conduction, when the clock signal exhibits an active level, between the second node and a fourth node to attain on the fourth node a fourth signal substantially the same as the second signal; and
latching the third signal on the third node.

16. The method of claim 14, further comprising:
propagating the clock signal through elements of a delay circuit in order to obtain the magnitude of the significant amount of delay.

17. The flip-flop of claim 2, wherein the delay circuit includes cascaded inverters through which the clock signal is propagated, a cumulative propagation delay of the cascaded inverters representing a magnitude of the significant amount of time.

18. The flip-flop of claim 8, wherein the delay circuit includes cascaded inverters through which the clock signal is propagated, a cumulative propagation delay of the cascaded inverters representing a magnitude of the significant amount of time.

19. The flip-flop of claim 3, wherein each of the first and second switching elements is an NMOS transistor.

20. The flip-flop of claim 7, wherein each of the first and second switching elements is an NMOS transistor.
